(19) United States
(12) Patent Application Publication
(10) Pub. No.: US 2025/0385150 A1
(43) Pub. Date: Dec. 18, 2025

(54) PACKAGING DEVICE

(71) Applicant: LITE-ON OPTO TECHNOLOGY (CHANGZHOU) CO., LTD., CHANGZHOU CITY (CN)

(72) Inventors: HSUEH-HAN WU, TAIPEI CITY (TW); Lei Zhang, CHANGZHOU CITY (CN)

(21) Appl. No.: 18/908,823

(22) Filed: Oct. 8, 2024

(30) Foreign Application Priority Data
Jun. 18, 2024 (CN) 202410793553.0

(51) Int. Cl. H01L 23/31; H01L 23/00; H01L 23/29; H01L 25/065

(52) U.S. Cl. CPC H01L 23/3135; H01L 23/296; H01L 23/3121; H01L 24/48; H01L 25/0655; H01L 2224/48091; H01L 2224/48225; H01L 2924/1811; H01L 2924/186

(57) ABSTRACT

A packaging device is provided. The packaging device includes a chip and a packaging layer. The chip is encapsulated by the packaging layer. A surface reinforcement layer is formed on an upper surface of the packaging layer. The packaging layer and the surface reinforcement layer have the same elements, but elemental contents in the packaging layer and the surface reinforcement layer are different.

### CROSS-REFERENCE TO RELATED PATENT APPLICATION

This application claims the benefit of priority to China Patent Application No. 202410793553.0, filed on Jun. 18, 2024 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a packaging device, and more particularly to a packaging device having a reinforcement layer.

### BACKGROUND OF THE DISCLOSURE

An existing LED packaging process involves disposing chips and wires on a circuit substrate (or a temporary substrate), molding the circuit substrate with a packaging material, and then cutting the circuit substrate into individual package structures. The packaging material needs to have a certain hardness for the molding and cutting processes. However, when the hardness of the packaging material is too high, internal stress within the package structure can become excessive due to factors such as the environment and temperature during customer use, leading to reliability issues such as lead breakage or packaging material cracking. On the other hand, when the hardness of the packaging material is too low, hard debris generated during the cutting process of the circuit substrate (or the temporary substrate) can easily penetrate the packaging material, significantly affecting the appearance and functionality of the product. Therefore, selecting an appropriate packaging material is crucial.

A common solution involves coating the packaging material with anti-adhesive agents to reduce debris adhesion to the surface of the packaging material. However, this approach increases the complexity of the process and introduces solvent handling issues, with only marginal improvement in effectiveness. Additionally, as package sizes continue to shrink, the number of the cuttings in the process increases, leading to more debris generation. Consequently, the approach of coating anti-adhesive agents is becoming less effective in preventing debris penetration.

Therefore, improving the overall packaging quality through structural and material modifications has become one of the important issues to be addressed in this field.

### SUMMARY OF THE DISCLOSURE

In response to the above-referenced technical inadequacy, the present disclosure provides a packaging device.

In order to solve the above-mentioned problems, one of the technical aspects adopted by the present disclosure is to provide a packaging device. The packaging device includes a chip and a packaging layer. The chip is encapsulated by the packaging layer. A reinforcement layer is formed on an upper surface of the packaging layer. The packaging layer and the reinforcement layer have the same elements, but elemental contents in the packaging layer and the reinforcement layer are different.

Therefore, in the packaging device provided by the present disclosure, by virtue of “the reinforcement layer being formed on an upper surface of the packaging layer” and “the packaging layer and the reinforcement layer having the same elements, but elemental contents in the packaging layer and the reinforcement layer being different,” the packaging device has appropriate surface hardness to avoid debris penetration after cutting, and can overcome the reliability issues of the packaging device caused by excessive internal stress.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a cross-sectional schematic side view of a packaging device according to a first embodiment of the present disclosure;

FIG. 2 to FIG. 4 are schematic views of a procedure for manufacturing the packaging device according to the first embodiment of the present disclosure;

FIG. 5 is a cross-sectional schematic side view of the packaging device according to a second embodiment of the present disclosure;

FIG. 6 is an X-ray photoelectron spectroscopy of a surface of the packaging device in Examples 1 to 3 and Comparative Example 1;

FIG. 7 is a superposition enlarged view of a silicon signal peak in FIG. 6;

FIG. 8 is a superposition enlarged view of an oxygen signal peak in FIG. 6; and

FIG. 9 is a superposition enlarged view of a carbon signal peak in FIG. 6.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

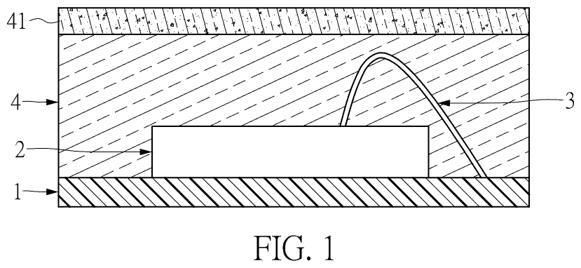

Referring to FIG. 1, a packaging device of a first embodiment of the present disclosure includes a circuit board 1, a chip 2, a wire 3, and a packaging layer 4.

The chip 2 is disposed on the circuit board 1. Two opposite ends of the wire 3 are respectively electrically connected with the chip 2 and a conductive structure on the circuit board 1. Accordingly, the chip 2 can be electrically connected with an external circuit sequentially through the wire 3 and the conductive structure. The packaging layer 4 is disposed on the circuit board 1. The chip 2 and the wire 3 are completely encapsulated by the packaging layer 4, thereby providing a protective effect.

A reinforcement layer 41 is formed on an upper surface (the surface away from the circuit board 1) of the packaging layer 4. A hardness of the reinforcement layer 41 is higher than a hardness of the packaging layer 4. Specifically, the hardness of the reinforcement layer 41 is at least 2H, and preferably greater than or equal to 3H. Therefore, during a subsequent cutting process, substrate debris is less likely to penetrate the reinforcement layer 41. In addition, the reinforcement layer 41 can further enhance the protective effect to the chip 2.

Since the reinforcement layer 41 is only formed on the upper surface of the packaging device, the chip 2 is still encapsulated by the comparatively soft packaging layer 4, thus reliability issues caused by wire breakage or resin cracking due to excessive internal stress within the packaging device can be avoided.

Since the packaging layer 4 and the reinforcement layer 41 are formed from the same packaging material, the packaging layer 4 and the reinforcement layer 41 contain the same elements. The difference between the packaging layer 4 and the reinforcement layer 41 is that the reinforcement layer 41 is further implemented by a surface treatment process. During the surface treatment process, the elemental contents of the packaging material are changed, thereby resulting in the formation of the reinforcement layer 41 and imparting different surface characteristics to the packaging device. Compared to disposing an additional reinforcement layer, the formation of the reinforcement layer 41 by the surface treatment process of the present disclosure is simpler, incurs a lower cost, and offers higher manufacturing yields.

The packaging layer 4 and the reinforcement layer 41 are formed from the same packaging material, such that the packaging layer 4 and the reinforcement layer 41 are integrally formed. Although a distinct interface is not present between the packaging layer 4 and the reinforcement layer 41 from the appearance, instrumental analysis reveals significant differences in elemental contents and surface characteristics between the packaging layer 4 and the reinforcement layer 41. The elemental contents and the surface characteristics of the packaging layer 4 and the reinforcement layer 41 are described later.

The method for manufacturing the packaging device includes steps of: disposing the chip 1 (step S1); forming the packaging layer 4 (step S2); and performing a surface treatment process (step S3). An optional cutting process (step S4) can also be implemented.

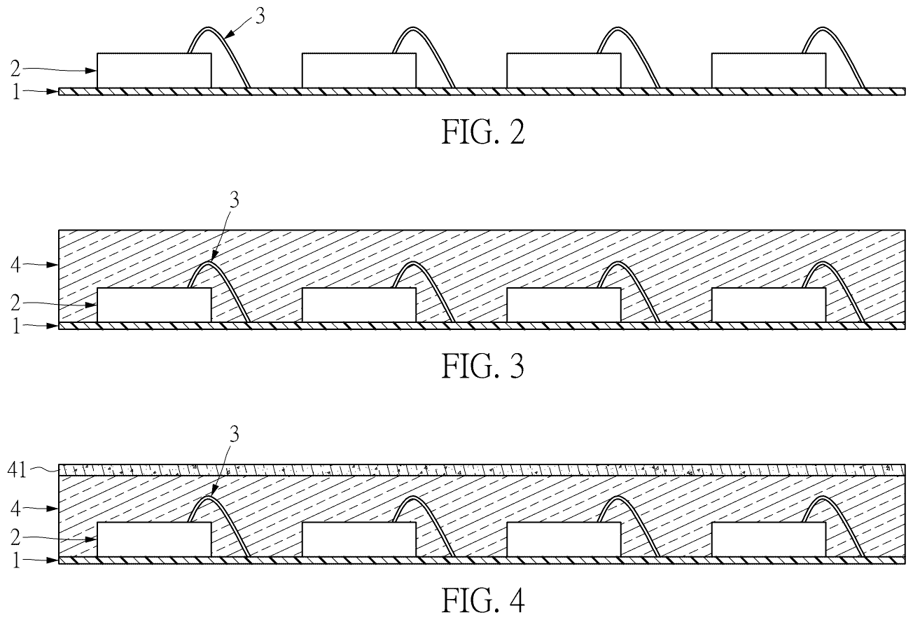

In step S1, the chip 2 is disposed on the circuit board 1, as shown in FIG. 2. A material of the circuit board 1 can be a ceramic substrate, an aluminum nitride substrate, an aluminum oxide substrate, a silicon substrate, or a printed circuit board, but the present disclosure is not limited thereto. A quantity of the chip 2 can be one or more. When the chips 2 are plural in quantity, the plurality of chips 2 are arranged at intervals, and each of the chips 2 is electrically connected to a conductive circuit (not shown) on the circuit board 1 via the wire 3. In this embodiment, the chip 2 is a vertical chip and is electrically connected to the circuit board 1 via the wire 3, but the present disclosure is not limited thereto. A flip-chip can also be employed such that the chip 2 can be electrically connected to the circuit board 1 without the use of the wire 3.

In step S2, the packaging layer 4 is formed from resin through a molding process, as shown in FIG. 3. For example, the resin is preferably a phenyl silicone, which has better optical characteristics and appropriate hardness, but the present disclosure is not limited thereto. Other resins can also be used to form the packaging layer 4.

In step S3, the surface treatment process can be an ultraviolet ozone treatment process. Under an ozone atmosphere, a high-energy ray (e.g., ultraviolet light) is applied to the upper surface of the packaging layer 4 to form the reinforcement layer 41, as shown in FIG. 4. It should be noted that the reinforcement layer 41 in FIG. 4 is not drawn to actual dimensions, and the proportions in the figure are for illustrative purposes only.

Some of the silicon-carbon (Si-C) bonds in the silicone is broken by the high-energy ray, and then react with oxygen free radicals in the environment to form silicon-oxygen (Si—O) bonds. Therefore, after the surface treatment process, the content of Si—O bonds in the reinforcement layer 41 is higher than the content of Si—O bonds in the packaging layer 4, and the content of Si-C bonds in the reinforcement layer 41 is lower than the content of Si-C bonds in the packaging layer 4. In addition, the formation of Si—O bonds can increase the cross-linking degree of the silicone.

The breaking and formation of these bonds also change the elemental contents of the reinforcement layer 41. The formation of Si—O bonds increases the content of silicon and oxygen elements in the reinforcement layer 41. Therefore, the amount of silicon element in the packaging layer 4 is lower than the amount of silicon element in the reinforcement layer 41, and the amount of oxygen element in the packaging layer 4 is lower than the amount of oxygen element in the reinforcement layer 41, while the amount of carbon element in the packaging layer 4 is higher than the amount of carbon element in the reinforcement layer 41.

Similarly, due to the change in elemental contents, the reinforcement layer 41 has a higher hardness (greater than 2H), a higher surface hydrophilicity (contact angle smaller than 80 degrees), and a lower powder-adhesion rate (powder-adhesion rate being equal to or lower than 0.6%) compared to the packaging layer 4.

In certain embodiments, the amount of silicon element in the reinforcement layer 41 ranges from 15% to 33%, the amount of oxygen element in the reinforcement layer 41 ranges from 28% to 60%, and the amount of carbon element in the reinforcement layer 41 ranges from 18% to 55%, but the present disclosure is not limited thereto. When the elemental contents of the reinforcement layer 41 are within the abovementioned ranges, the upper surface of the packaging device can have excellent surface characteristics to meet various processing conditions.

The thickness of the reinforcement layer 41 can range from 20 nanometers to 150 nanometers, for example, a value of the thickness is an integer between 20 and 150. When the reinforcement layer 41 is too thin, the reinforcement layer 41 cannot provide the desired protective effect. When the reinforcement layer 41 is too thick, an internal stress in the packaging device increases, thereby increasing manufacturing cost and the duration of the surface treatment process.

The thickness of the reinforcement layer 41 can be controlled by adjusting the parameters of the surface treatment process. Specifically, in order to promote the formation of Si—O bonds, the surface treatment process can be performed at a temperature ranging from 75° C. to 95° C. in an ozone atmosphere having a concentration greater than 50%, preferably greater than 60%, and more preferably greater than 70%. The high-energy ray can be ultraviolet light having a wavelength ranging from 150 nanometers to 260 nanometers. In an exemplary embodiment, the surface treatment process is simultaneously irradiated by a first ultraviolet light having a wavelength ranging from 150 nanometers to 200 nanometers and a second ultraviolet light having a wavelength ranging from 201 nanometers to 260 nanometers for a total duration of from 8 minutes to 20 minutes. A distance between an ultraviolet light source and the upper surface of the packaging layer 4 ranges from 15 millimeters to 60 millimeters, which can improve the reaction efficiency of the surface treatment process to form the reinforcement layer 41 having an appropriate thickness.

In addition to the ultraviolet ozone treatment process, the surface treatment process can also be a plasma treatment process or a high-energy ray treatment process, but the present disclosure is not limited thereto.

In step S4, the cutting process is performed according to the quantity of the chip 2, so as to obtain multiple packaging devices as shown in FIG. 1. After the cutting process, it was found that the formation of the reinforcement layer 41 can effectively reduce the amount of debris generated during the cutting process, and the cut packaging devices have smooth edges without burrs. Therefore, the manufacturing yield and reliability of the packaging devices can be greatly improved.

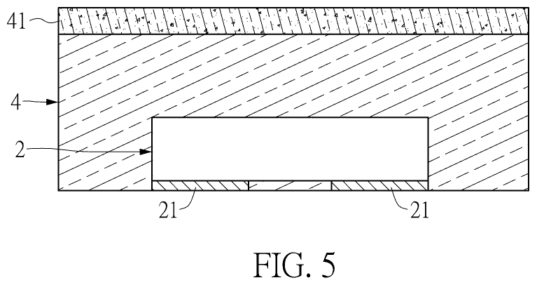

The packaging device of the present disclosure can also be applied to chip scale packaging (CSP). Referring to FIG. 5, the packaging device of a second embodiment of the present disclosure is similar to the packaging device of the first embodiment. The difference is that, the packaging device of the second embodiment does not include the circuit board 1 and the wire 3, and a flip-chip is adapted.

In the second embodiment, the packaging device includes a chip 2 and a packaging layer 4. The chip 2 has a conductive electrode 21, and the conductive electrode 21 is exposed from the packaging layer 4 to be electrically connected to an external circuit. The chip 2 is encapsulated by the packaging layer 4, and a reinforcement layer 41 is also formed on the upper surface of the packaging layer 4. A difference in the manufacturing of the packaging chip of the second embodiment from that of the first embodiment is that, a temporary substrate is used. The chip 2 is disposed on the temporary substrate and the packaging layer 4 is formed by molding. Subsequently, the surface treatment process is performed to form the reinforcement layer 41 on the packaging layer 4. Finally, the temporary substrate is removed after the cutting process.

### Experimental Data

According to the structure of the first embodiment, two types of silicone are used to manufacture the packaging devices in Example 1 (using Dow Corning OE6662® silicone) and Example 2 (using Dow Corning OE6650® silicone). Additionally, the packaging device in Comparative Example 1 (referred to as “C1” in Table 1) is manufactured using OE6662® silicone without forming the reinforcement layer (not subjected to the surface treatment process), and the packaging device in Comparative Example 2 (referred to as “C2” in Table 1) is manufactured using OE6650® silicone without forming the reinforcement layer.

In order to compare the effects of parameter adjustments on the properties of the reinforcement layer, the surface treatment process is performed at 85° C. and an ozone concentration of 80%, simultaneously being irradiated with UV light at wavelengths of 170 nm and 250 nm. In Examples 1-1 to 1-3 (referred to as “E1-1 to E1-3” in Table 1), the distance of the UV light source (referred to as “distance” in Table 1) and the duration of UV irradiation (referred to as “duration” in Table 1) are varied. Similarly, in Examples 2-1 to 2-3, different distances of the UV light source and different durations of UV irradiation are used. Specific parameters are listed in Table 1.

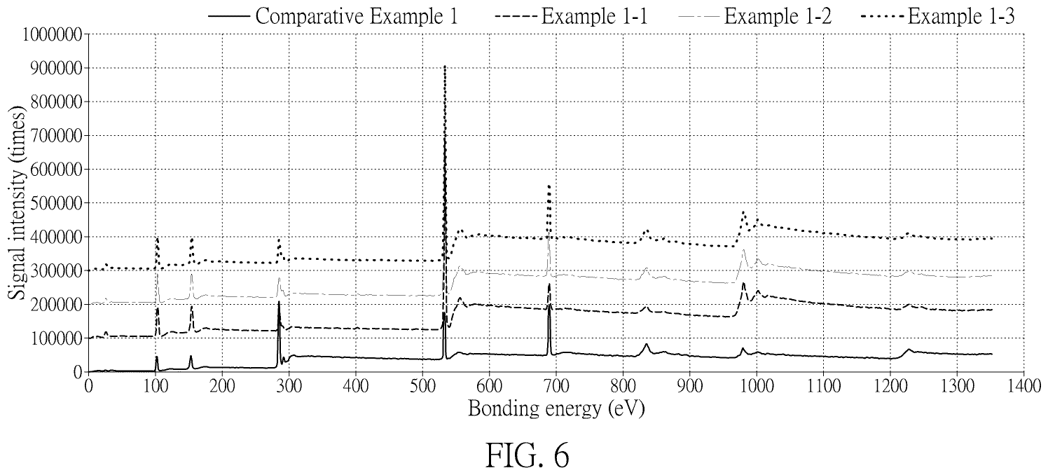

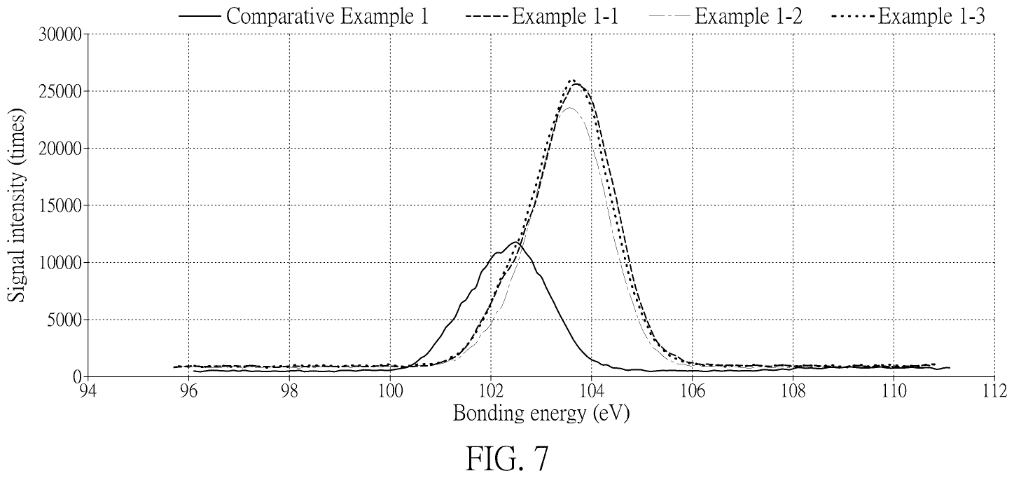

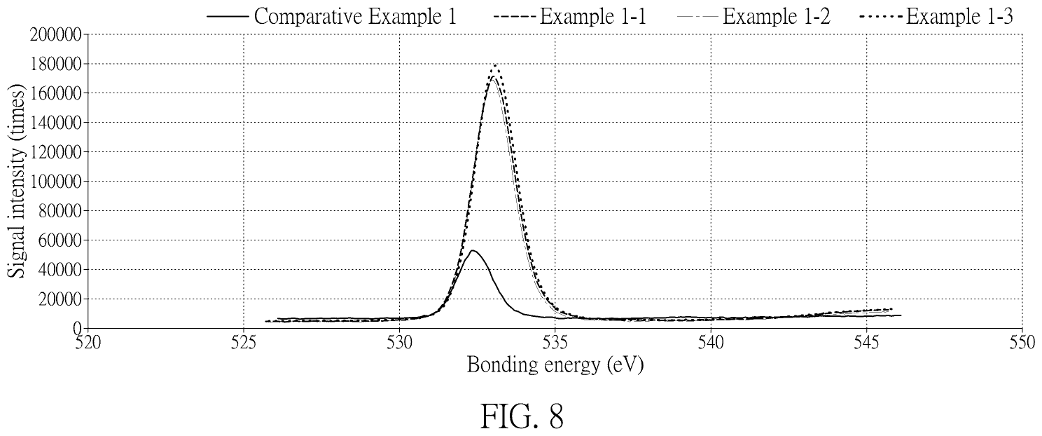

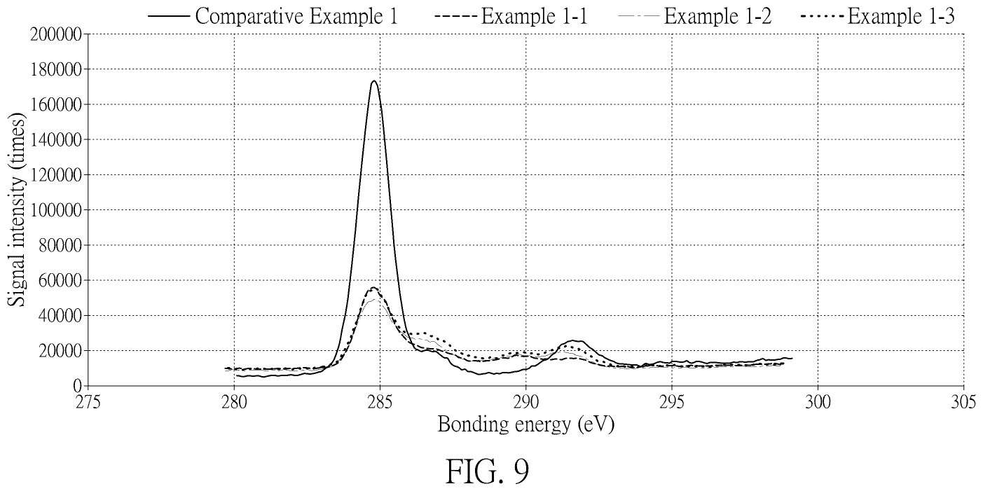

An X-ray photoelectron spectroscopy (XPS) is used to analyze a signal intensity at different binding energies on the surface of the packaging devices to further analyze the elemental content ratio. FIG. 6 shows the XPS results for Examples 1-1 to 1-3 and Comparative Example 1. FIG. 7 to FIG. 9 are respectively superposition enlarged views of a silicon signal peak, an oxygen signal peak, and a carbon signal peak in FIG. 6. Contact angle measuring instrument (brand: Huisheng Technology, model: NEMST-CAMI2008) is used to measure the contact angle of the surface of the packaging device. Mitsubishi sketch pencil (model: 9800DX (from 10B to 8H)) is used to scratch the surface of the packaging device to assess the hardness based on whether or not the pencil lead is fractured. The specific results are listed in Table 1.

The surface of the packaging devices is immersed in a phosphor powder pile, and weights of the packaging devices before and after immersion are compared to calculate the surface powder adhesion rate. The yield of the packaging devices is evaluated based on whether or not any debris penetrates the packaging devices after the cutting process. The yield is calculated as the number of qualified products divided by the total number of manufactured products. The evaluation results are listed in Table 1.

TABLE 1

| | | | Surface characteristic | | | | | | |
|---|---|---|---|---|---|---|---|---|---|
| | Surface | | | | | | | Surface | |
| | treatment | | | | | | | powder | |
| | process | | | | | Contact | | adhesion | |
| | Distance | Duration | Silicon | Oxygen | Carbon | angle | | rate | |
| | (mm) | (min) | (%) | (%) | (%) | (°) | Hardness | (%) | Yield |
| E1-1 | 20 | 15 | 25.97 | 52.90 | 21.13 | 70 | 5H | 0.1 | 95% |
| E1-2 | 50 | 15 | 23.28 | 52.23 | 24.49 | 80 | 3H | 0.3 | 90% |
| E1-3 | 20 | 10 | 23.97 | 50.76 | 25.27 | 78 | 4H | 0.3 | 91% |
| C1 | — | — | 14.68 | 16.51 | 68.81 | 93 | 1H | 0.7 | 72% |
| E2-1 | 20 | 15 | 15.78 | 32.56 | 51.13 | 43 | 5H | 0.2 | 92% |
| E2-2 | 50 | 15 | 16.76 | 33.24 | 49.91 | 41 | 3H | 0.5 | 90% |
| E2-3 | 20 | 10 | 16.82 | 35.59 | 47.36 | 40 | 4H | 0.6 | 90% |
| C2 | — | — | 2.19 | 8.09 | 88.82 | 97 | 1H | 0.9 | 70% |

According to the results in Table 1, the elemental content ratio of the reinforcement layer is indeed different from that of the packaging layer. The amount of silicon element in the reinforcement layer can range from 15% to 26%, the amount of oxygen element can range from 32% to 53%, and the amount of carbon element can range from 21% to 52%.

Further comparing the elemental content ratio of the reinforcement layer and the packaging layer, the amount of the silicon element in the reinforcement layer is 1.5 times to 7.7 times the amount of the silicon element in the packaging layer. The amount of the oxygen element in the reinforcement layer is 3.0 times to 4.4 times the amount of the oxygen element in the packaging layer. The amount of the carbon element in the reinforcement layer is 0.30 times to 0.58 times the amount of the carbon element in the packaging layer. In other embodiments, the content ratio of the silicon element in the reinforcement layer to the silicon element in the encapsulating layer can be a positive integer between 1.5 and 7.7. The content ratio of the oxygen element in the reinforcement layer to the oxygen element in the encapsulating layer can be 3.2, 3.4, 3.6, 3.8, 4.0, or 4.2. The content ratio of the carbon element in the reinforcement layer to the carbon element in the packaging layer can be 0.3, 0.4, 0.5, or 0.6.

According to the results in Table 1, when the distance between the ultraviolet light source and the surface of the packaging layer ranges from 15 mm to 25 mm and the irradiation time (duration) ranges from 12 minutes to 20 minutes, the reinforcement layer can have a high hardness, low surface powder adhesion rate, and high yield (Example 1-1 and Example 2-1).

### Beneficial Effects of the Embodiments

In conclusion, in the packaging device provided by the present disclosure, by virtue of “the reinforcement layer being formed on an upper surface of the packaging layer” and “the packaging layer and the reinforcement layer having the same elements, but contents of the elements in the packaging layer and the reinforcement layer being different,” the packaging device has appropriate surface hardness to avoid debris penetration after cutting, and can overcome the reliability issues of the packaging device caused by excessive internal stress.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A packaging device, comprising:
a chip; and
a packaging layer encapsulating the chip, wherein a reinforcement layer is formed on an upper surface of the packaging layer;
wherein the packaging layer and the reinforcement layer have the same elements, but elemental contents in the packaging layer and the reinforcement layer are different.

2. The packaging device according to claim 1, further comprising: a circuit board, wherein the chip is disposed on and electrically connected to the circuit board.

3. The packaging device according to claim 1, wherein an amount of silicon element in the packaging layer is lower than an amount of silicon element in the reinforcement layer.

4. The packaging device according to claim 1, wherein an amount of oxygen element in the packaging layer is lower than an amount of oxygen element in the reinforcement layer.

5. The packaging device according to claim 1, wherein an amount of carbon element in the packaging layer is higher than an amount of carbon element in the reinforcement layer.

6. The packaging device according to claim 1, wherein an amount of the silicon element in the reinforcement layer ranges from 15% to 26%.

7. The packaging device according to claim 1, wherein an amount of the oxygen element in the reinforcement layer ranges from 32% to 53%.

8. The packaging device according to claim 1, wherein an amount of the carbon element in the reinforcement layer ranges from 21% to 52%.

9. The packaging device according to claim 1, wherein a contact angle of the packaging layer is larger than a contact angle of the reinforcement layer.

10. The packaging device according to claim 1, wherein a contact angle of the reinforcement layer is smaller than or equal to 80 degrees.

11. The packaging device according to claim 1, wherein a hardness of the packaging layer is lower than a hardness of the reinforcement layer.

12. The packaging device according to claim 11, wherein a hardness of the reinforcement layer is higher than or equal to 3H.

13. The packaging device according to claim 1, wherein the packaging layer is formed from a phenyl silicone.

14. The packaging device according to claim 1, wherein a thickness of the reinforcement layer ranges from 20 nm to 150 nm.

15. The packaging device according to claim 1, wherein the packaging layer and the reinforcement layer are integrally formed.

16. The packaging device according to claim 1, wherein an amount of the silicon element in the reinforcement layer is 1.5 times to 7.7 times an amount of the silicon element in the packaging layer.

17. The packaging device according to claim 1, wherein an amount of the oxygen element in the reinforcement layer is 3.0 times to 4.4 times an amount of the oxygen element in the packaging layer.

18. The packaging device according to claim 1, wherein an amount of the carbon element in the reinforcement layer is 0.30 times to 0.58 times an amount of the carbon element in the packaging layer.

19. The packaging device according to claim 1, wherein a powder-adhesion rate of a surface of the reinforcement layer is equal to or lower than 0.6%.
